(19) United States
(12) Patent Application Publication
(10) Pub. No.: US 2021/0057464 A1
(43) Pub. Date: Feb. 25, 2021

(54) IMAGE SENSING DEVICE

(71) Applicant: SK hynix Inc., Icheon-si (KR)

(72) Inventor: Jae Won Lee, Cheongju-si (KR)

(21) Appl. No.: 16/686,720

(22) Filed: Nov. 18, 2019

(30) Foreign Application Priority Data
Aug. 23, 2019 (KR) 10-2019-0103667

(51) Int. Cl. H01L 27/146

(52) U.S. Cl. CPC H01L 27/1461; H01L 27/1463; H01L 27/14629; H01L 27/14645

(57) ABSTRACT

An image sensing device includes a semiconductor substrate and metal lines. The semiconductor substrate includes a first surface and a second surface on two opposite sides of the semiconductor substrate, and includes a plurality of unit pixels, each of which is configured to generate a pixel signal based on light incident upon the first surface. The metal lines are disposed over the second surface of the semiconductor substrate, and carry the pixel signal generated from the semiconductor substrate and electrical signals used to generate the pixel signal. At least one of the metal lines includes an anti-reflection structure having a shape to direct light that propagates in the semiconductor substrate and is reflected from the metal lines to directions other than a direction toward the semiconductor substrate.

### CROSS-REFERENCE TO RELATED APPLICATION

This patent document claims the priority and benefits of Korean patent application No. 10-2019-0103667, filed on Aug. 23, 2019, which is hereby incorporated in its entirety by reference.

### TECHNICAL FIELD

The technology and implementations disclosed in this patent document relate to an image sensing device for measuring a distance between the image sensing device and an object being measured.

### BACKGROUND

With the development of technologies in the computer and communication industries, the demand for high-quality, high-performance image sensors is rapidly increasing in various devices such as digital cameras and smartphones.

Image sensors may be classified into charge coupled device (CCD) image sensors and complementary metal oxide semiconductor (CMOS) image sensors. CMOS image sensors are now widely used due to certain advantages over CCD image sensors, including, e.g., lower power consumption, lower production costs, and smaller size. Such advantages of CMOS image sensors make these sensors better suited for implementations in mobile devices.

### SUMMARY

The embodiments of the disclosed technology relate to an image sensing device that can prevent light that propagates in a semiconductor substrate from being reflected from a metal line, thereby preventing reflected light from propagating to the semiconductor substrate.

In an embodiment of the disclosed technology, an image sensing device may include a semiconductor substrate including a first surface and a second surface on two opposite sides of the semiconductor substrate, and configured to include a plurality of unit pixels, each of which is configured to generate a pixel signal based on light incident upon the first surface, and metal lines disposed over the second surface of the semiconductor substrate, and configured to carry the pixel signal generated from the semiconductor substrate and electrical signals used to generate the pixel signal. At least one of the metal lines may include an anti-reflection structure having a shape to direct light that propagates in the semiconductor substrate and is reflected from the metal lines to directions other than a direction toward the semiconductor substrate.

In another embodiment of the disclosed technology, an image sensing device may include a substrate layer including a plurality of unit pixels, each of which is configured to generate a pixel signal based on light incident upon a first surface, and metal lines disposed over a second surface of the substrate layer located to face away from the first surface, and coupled to the substrate layer. The metal lines may include serrated patterns formed at a surface acing the substrate layer.

In another embodiment of the disclosed technology, an image sensing device may include a semiconductor substrate including a first surface and a second surface facing the first surface, and configured to have a plurality of unit pixels, each of which generates a pixel signal in response to light incident upon the first surface, and metal lines disposed over the second surface of the semiconductor substrate, and configured to transmit not only the pixel signal generated from the semiconductor substrate, but also signals needed to generate the pixel signal. Each of the metal lines may include an anti-reflection structure for preventing light having penetrated the semiconductor substrate from being reflected into the semiconductor substrate.

In another embodiment of the disclosed technology, an image sensing device may include a substrate layer provided with a plurality of unit pixels, each of which is configured to generate a pixel signal through conversion of light incident upon a first surface, and metal lines disposed over a second surface of the substrate layer located to face the first surface, and coupled to the substrate layer. The metal lines may include serrated patterns formed at a surface located to face the substrate layer.

It is to be understood that the foregoing general description, the accompanying drawings, and the following detailed description in this patent document are illustrative and explanatory of technical features and implementations of the disclosed technology.

### BRIEF DESCRIPTION OF THE DRAWINGS

FIG. 1 illustrates an example of an image sensing device based on some implementations of the disclosed technology.

FIG. 2 is a cross-sectional view illustrating an example of unit pixel region of a pixel array shown in FIG. 1.

FIGS. 3A to 3F are cross-sectional views illustrating processes for forming the structure of FIG. 2.

FIG. 4 is a cross-sectional view illustrating another anti-reflection structure based on some implementations of the disclosed technology.

FIG. 5 is a cross-sectional view illustrating another anti-reflection structure based on some implementations of the disclosed technology.

FIG. 6 is a cross-sectional view illustrating another anti-reflection structure based on some implementations of the disclosed technology.

### DETAILED DESCRIPTION

Reference will now be made in detail to certain embodiments, examples of which are illustrated in the accompanying drawings. Wherever possible, the same reference numbers will be used throughout the drawings to refer to the same or similar parts.

A three-dimensional (3D) image sensor can be used for object scanning, measure distance, 3D photography and much more. In acquiring 3D images using image sensors, color information of the 3D image and the distance (or depth) between the image sensor and an object being measured are usually used.

The distance between the object and the image sensor may be acquired in two ways: passive method and active method. The passive method may obtain the distance between the object and the image sensor using only image information of the object being measured without illuminating light to the object. The passive method can be applied to a stereo camera.

On the other hand, the active method illuminates light by a light source to the object to measure the distance. Examples of the active method include a triangulation method and a Time of Flight (TOF) method. The triangulation method measures the distance based on light illuminated to the object and light reflected from the object. The TOF method measures the distance by measuring the round-trip time of the illuminated light.

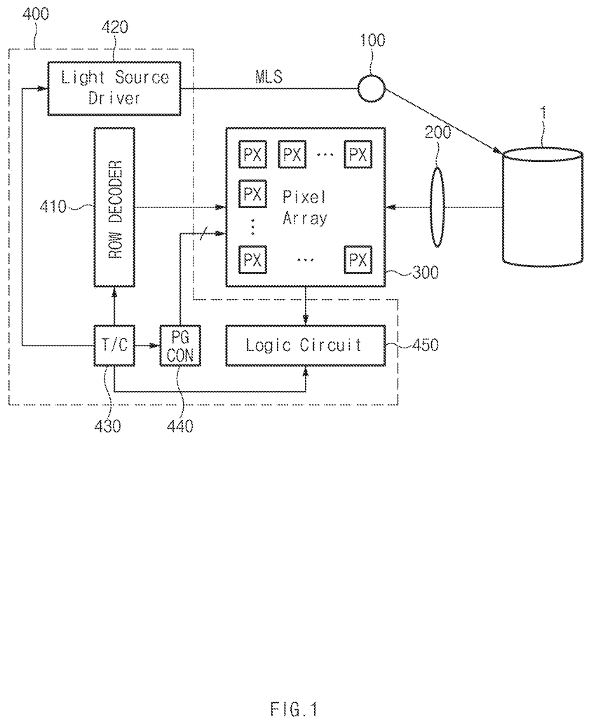

FIG. 1 is a block diagram illustrating an example of an image sensing device based on some implementations of the disclosed technology.

The image sensing device may measure the distance between the image sensing device and an object being measured using the time-of-flight (TOF) techniques. The image sensing device may include a light source 100, a lens module 200, a pixel array 300, and a control circuit 400.

The light source 100 may illuminate light to a target object 1 upon receiving a clock signal MLS from the control circuit 400. Examples of the light source 100 may include a laser diode (LD), a light emitting diode (LED) for emitting infrared light or visible light, a near infrared laser (NIR), a point light source, a monochromatic light source combined with a white lamp or a monochromator, and a combination of other laser sources. For example, the light source 100 may illuminate infrared light at a wavelength of 800 to 1000 nm. Although FIG. 1 shows only one light source 100 for convenience of description, it is to be noted that a plurality of light sources may also be arranged in the vicinity of the lens module 200.

The lens module 200 may collect light reflected from the target object 200, and may allow the collected light to be focused onto pixels (PXs) of the pixel array 300. The lens module 200 may include a focusing lens having a surface formed of glass or plastic material or another cylindrical optical element having a surface formed of glass or plastic material. The lens module 200 may include a focusing lens having a convex structure.

The pixel array 300 may include a plurality of unit pixels (PXs) arranged in a two-dimensional (2D) array. In one example, the unit pixels are arranged in first and second directions perpendicular to each other. The unit pixels (PXs) may be formed in a semiconductor substrate, and each unit pixel PX may convert light received through the lens module 200 into electrical signals corresponding to the received light such that each unit pixel can output a pixel signal. In some embodiments of the disclosed technology, the pixel signal may include information associated with the distance to the target object 1. The unit pixel (PX) may be a current-assisted photonic demodulator (CAPD) pixel for detecting electrons that are generated in a substrate by incident light, based on electric potential difference. In some cases, the incident light can penetrate the substrate where the pixel array 300 is formed, and the light propagating in the substrate can possibly be reflected from interconnects arranged over the substrate. To reduce the reflections within the pixel array 300, the pixel array 300 may further include an anti-reflection structure. In some implementations, the anti-reflection structure may include a serrated structure on interconnects (e.g., metal lines) formed over the substrate to carry pixel signals and/or control signals. In one example, the anti-reflection structure may be formed by etching at least one side of an interconnect such that the at least one side of an interconnect includes inclined portions consecutively arranged along the at least one side of an interconnect. The anti-reflection structure will hereinafter be described in detail.

The control circuit 400 may illuminate light to the target object 1 by controlling the light source 100 and associated optics. The control circuit 400 may process each pixel signal corresponding to light reflected from the target object 1 by operating unit pixels (PXs) of the pixel array 300 to measure the distance to the surface of the target object 1.

The control circuit 400 may include a row decoder 410, a light source driver 420, a timing controller 430, a photogate controller 440, and a logic circuit 450.

The row decoder 410 may be used to select desired unit pixels (PXs) of the pixel array 300 in response to a timing signal generated by the timing controller 430. For example, the row decoder 410 may generate a control signal to select at least one of the plurality of row lines. The control signal may include a selection signal for controlling the selection transistor and a transmission (Tx) signal for controlling transfer gates.

The light source driver 420 may generate a clock signal MLS that can be used to operate the light source 100 in response to a control signal from the timing controller 430. The light source driver 42 may supply at least one of the clock signal MLS or information about the clock signal MLS to the photogate controller 28.

The timing controller 430 may generate a timing signal to control the row decoder 410, the light source driver 420, the photogate controller 440, and the logic circuit 450 at desired timings.

The photogate controller 440 may generate photogate control signals based on control signals generated by the timing controller 430 to apply the photogate control signals to the pixel array 300 at desired timings.

The logic circuit 450 may process pixel signals received from the pixel array 300 responsive to timing and control signals of the timing controller 430. In some implementations, the logic circuit 450 may be used to calculate the distance to the target object 1. The logic circuit 450 may include a correlated double sampler (CDS) circuit for performing correlated double sampling (CDS) on the pixel signals generated from the pixel array 300. In one example, the CDS circuit may be used to remove an offset value of pixels by sampling a pixel signal twice so that the difference is taken between these two samples. In addition, the logic circuit 450 may include an analog-to-digital converter (ADC) for converting analog output signals of the CDS circuit into digital signals.

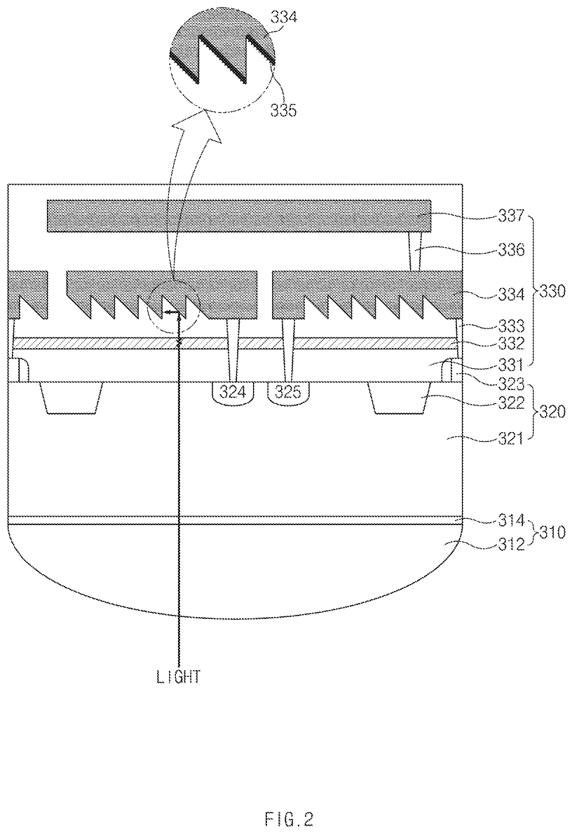

FIG. 2 is a cross-sectional view illustrating an example of unit pixel region of the pixel array 300 shown in FIG. 1.

As shown in FIG. 2, the pixel array 300 may include a light reception layer 310, a substrate layer 320, and an interconnect layer (e.g., metal layer) 330.

The light reception layer 310 may be used to direct light beams that are reflected from the target object 1 toward a semiconductor substrate 321. The light reception layer 310 may include a microlens 312 and an anti-reflection layer 314 that are sequentially stacked over the semiconductor substrate 321. The anti-reflection layer 314 may be formed of, for example, silicon oxynitride (SiON), silicon carbide (SiC), silicon carbon nitride (SiCN), or silicon oxycarbide (SiCO).

The substrate layer 320 may include the semiconductor substrate 321 having a first surface and a second surface. The light reception layer 310 may be formed over the first surface of the semiconductor substrate 321, and the interconnect layer 330 may be formed over the second surface facing away from the first surface. The semiconductor substrate 321 may generate electron-hole pairs based on incident light received through the first surface. A device isolation layer 322 may be formed to electrically isolate active regions from neighboring active regions and other components. The device isolation layer 322 may be formed on the second surface. The device isolation layer 322 may be formed in a shallow trench isolation (STI) structure. Pixel transistors 323 for reading out pixel signals may be formed on the active regions defined by the device isolation layer 322. In addition, each of the active regions may include a control region 324 and a detection region 325, which are coupled to a metal layer 334 of the interconnect layer 330. The detection region 324 may generate carrier currents (e.g., hole currents) in the semiconductor substrate 321 based on a voltage at the metal line 334. In one example, when electrons generated by light incident upon the semiconductor substrate 321 are moving by carrier currents, the detection region 325 may capture the moving electrons. The control region 324 may include a P-type impurity region. The control region 324 may include a P (+) diffusion region and a P-well. The detection region 325 may include an N-type impurity region. The detection region 325 may include an N (+) diffusion region and an N-well.

The interconnect layer 330 may include a plurality of stacked interlayer insulation layers 331 and a plurality of metal lines 334 and 337 stacked as a plurality of layers within the interlayer insulation layers 331. Each interlayer insulation layers 331 may include at least one of an oxide film or a nitride film. Each of the metal lines 334 and 337 may include at least one of aluminum (Al), copper (Cu), or tungsten (W). The metal lines 334 and 337 may be used to carry electrical signals (voltage) to generate the pixel signal and carry the pixel signal generated from the substrate layer. The metal lines 334 and 337 at different levels may be coupled to each other through a contact plug 336. In addition, the metal line 334 may be coupled to the control region 324, the detection region 325 of the semiconductor substrate 321, and the pixel transistor 323 (through contact plug 333).

The interconnect layer 330 based on some embodiments of the disclosed technology may include an anti-reflection structure. In more detail, after light is first incident upon the first surface of the semiconductor substrate 321 and is transmitted through the semiconductor substrate 321, the anti-reflection structure may prevent light that propagates in the semiconductor substrate 321 from being reflected from the metal lines, thereby preventing reflected light propagating to the semiconductor substrate 321.

In some implementations, the time-of-flight (TOF) sensor utilizes long-wavelength light. As a result, such long-wavelength light received through the light reception layer 310 is more prone to propagate in the semiconductor substrate 321, and this light can be reflected from the metal lines of the interconnect layer 330 and directed to the semiconductor substrate 321. In some implementations, the TOF sensor may calculate the distance between the image sensor and the object being measured based on a difference in signals for each phase. In this case, when the light beams reflected from the metal lines propagate to the semiconductor substrate, such reflected light beams may be added to another phase instead of the original phase of the light beams, resulting in an error in distance calculation.

Some embodiments of the disclosed technology can avoid such an error by preventing the light beams from reflecting at the metal line and/or by preventing reflected light beams from propagating to the semiconductor substrate 321.

In some implementations, in order to prevent the light beams from reflecting toward the semiconductor substrate 321, the metal line 334 may include a serrated pattern at its surface. In one example, the metal line 334 may include a serrated pattern at the surface facing the semiconductor substrate 321. The serrated pattern of the metal line is structured to direct the light reflected at its surface to directions other than the semiconductor substrate 321, as depicted by the arrows of FIG. 2, the reflected light may be directed to another direction without being re-directed to the semiconductor substrate 321.

In some embodiments of the disclosed technology, the interconnect layer 330 may further include a light delay film 332 for reducing the propagation speed of light in the semiconductor substrate 321. The light delay film 332 may be disposed between the semiconductor substrate 321 and the metal line 334. The light delay film 332 may include at least one of a high-permittivity material film or a high-permeability material film. In this case, the high-permittivity material film may include at least one of aluminum oxide (Al₂O₃), hafnium oxide (HfO₂), zirconium oxide (ZrO₂), hafnium silicate (HfSiO, HfSiO₄), zirconium silicon oxide (ZrSiO), yttrium oxide (Y₂O₃), tantalum oxide (Ta₂O₅), or titanium oxide (TiO₂). The high-permeability material film may include a ferromagnetic material.

In some embodiments of the disclosed technology, undesirable reflections of light toward the semiconductor substrate 321 can be avoided in two steps: (1) the propagation speed of the light having penetrated the semiconductor substrate 321 decreases due to the light delay film 332; and (2) the light that has passed through the light delay film 332 may be directed to directions other than the direction toward the semiconductor substrate 321.

In some embodiments of the disclosed technology, an anti-reflection film 335 may be further formed over the surface of the serrated pattern of the metal line 334 so that the anti-reflection film 335 can effectively prevent reflection of light.

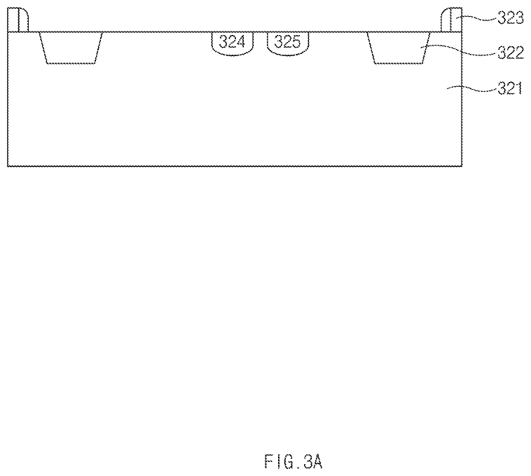

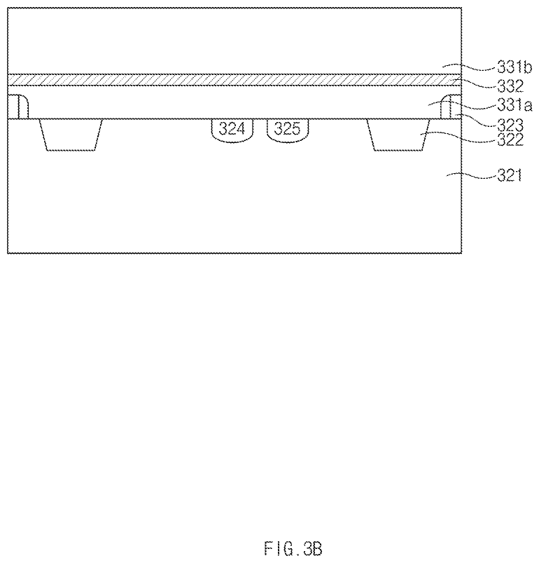

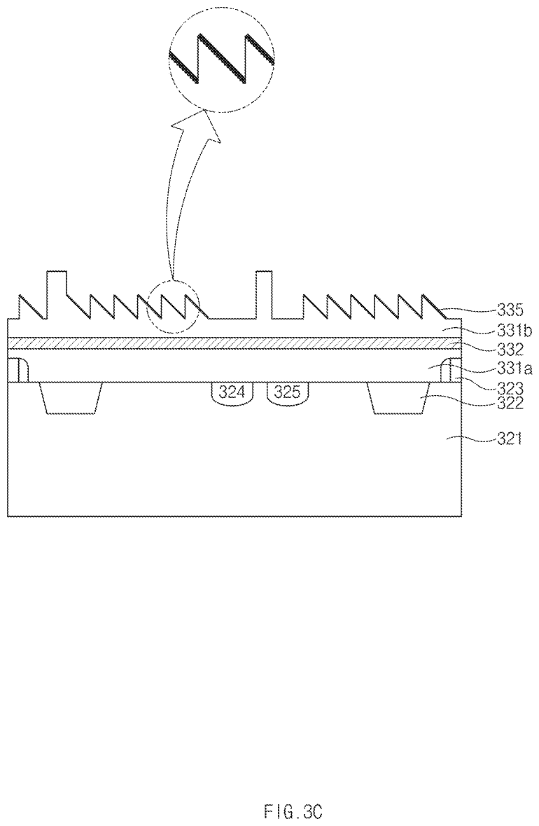

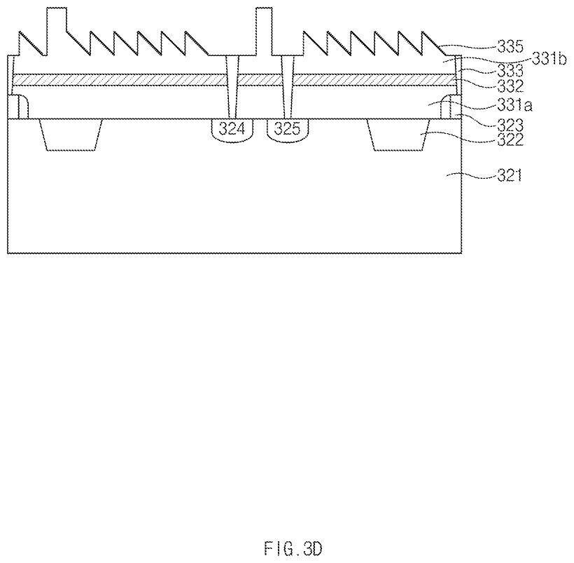

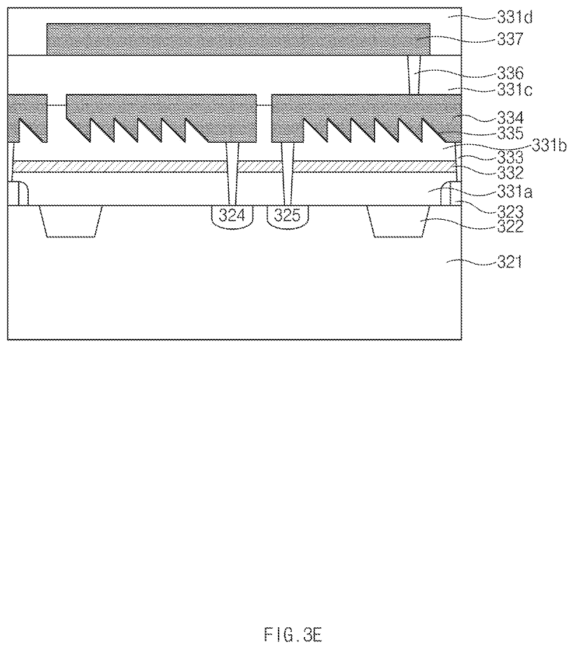

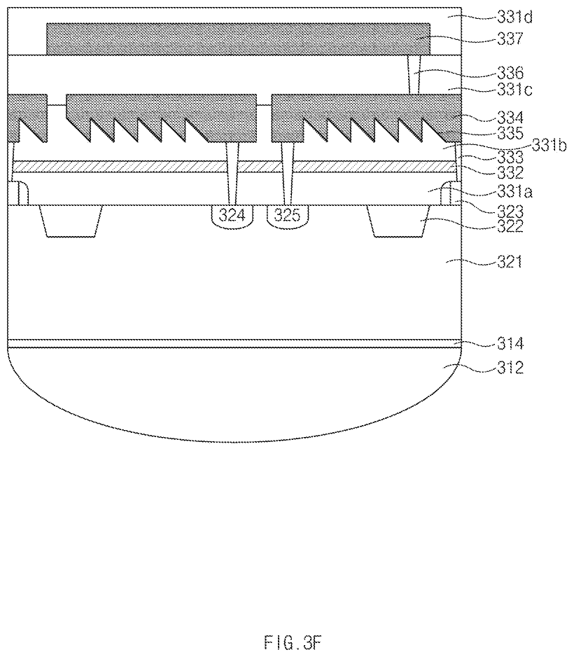

FIGS. 3A to 3F are cross-sectional views illustrating processes for forming the structure of FIG. 2.

As shown in FIG. 3A, after a device isolation trench is formed by patterning and etching a second surface to a predetermined depth, an insulation layer may be formed to fill the trench, resulting in formation of a device isolation layer 322 defining the active region.

Subsequently, pixel transistors 323 for reading out pixel signals may be formed over the active region. In addition, P-type impurities and N-type impurities may be implanted into the active region formed at the center of each pixel, such that the control region 324 and the detection region 325 can be formed.

As shown in FIG. 3B, a first interlayer insulation layer 331a may be formed over the substrate layer 320 including the pixel transistors 323, the control region 324, and the detection region 325, and the light delay film 332 may be formed over the first interlayer insulation layer 331a.

Subsequently, a second interlayer insulation layer 331b may be formed over the light delay film 332.

Each of the first and second interlayer insulation layers 331a and 331b may include at least one of an oxide film or a nitride film. The light delay film 332 may include at least one of the high-permittivity material film or the high-permeability material film.

As shown in FIG. 3C, a specific region in which the metal line 334 will be formed may be formed by etching part of the second interlayer insulation layer 331b, such that a trench having a bottom surface formed in a serrated pattern may be formed. In some implementations, diagonal regions of the serrated pattern in the trench may be formed in a staircase shape.

In some implementations, the serrated pattern is not formed in the region to be used for formation of the contact plug on the bottom surface of the trench.

Subsequently, the anti-reflection film 335 may be formed in some regions of the bottom surface of the trench.

For example, the anti-reflection film 335 may be formed along the surface of the diagonal region of the serrated pattern on the bottom surface of the trench.

As shown in FIG. 3D, a specific region to be used for formation of the contact plug may be formed by etching the bottom surface of the trench, resulting in formation of a contact hole. For example, a region having no serrated pattern may be etched from the bottom surface of the trench, resulting in formation of the contact hole.

Subsequently, a conductive material film may be formed to fill the contact hole, resulting in formation of a contact plug 333 that is coupled to each of the control region 324, the detection region 325, and the pixel transistor 323. In one example, the conductive material film may include a metal film (e.g., tungsten W).

As shown in FIG. 3E, after a metal film is formed over the second interlayer insulation layer 331b and the anti-reflection film 335 to fill the trench, the metal film may be patterned, resulting in formation of the metal line 334.

Subsequently, the interlayer insulation layer 331c may be formed over the metal line 334 and the second interlayer insulation layer 331b. Subsequently, the interlayer insulation layer 331c may be etched to expose the metal line 334 in a manner that the contact hole is formed, and the conductive material film may be formed to fill the contact hole in a manner that the contact plug 336 is formed in the interlayer insulation layer 331c.

After the metal film is formed over the interlayer insulation layer 331c, the metal film is patterned, resulting in formation of the metal line 337. Subsequently, the interlayer insulation layer 331d may be formed over the metal line 337 and the interlayer insulation layer 331c.

As shown in FIG. 3F, the anti-reflection film 314 and the microlens 312 may be sequentially formed over the first surface of the semiconductor substrate 321.

The serrated pattern is shown in FIG. 2 by way of example, and thus the metal line may have any shape that can direct light beams reflected from the surface of the metal line to directions other than the direction toward the semiconductor substrate.

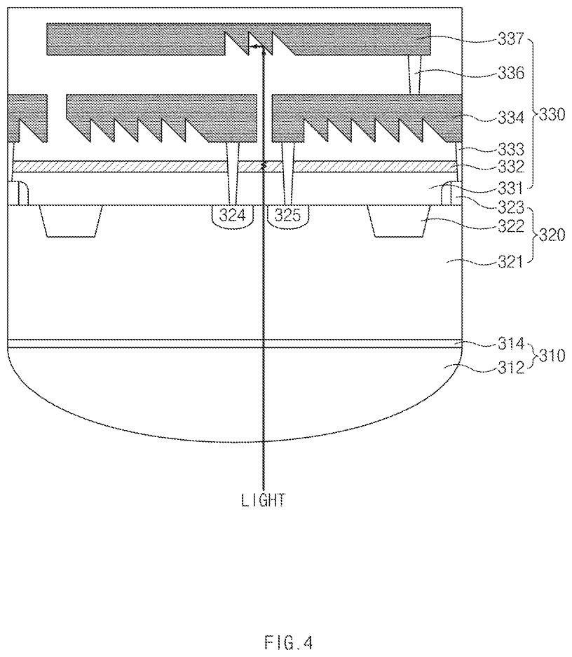

FIG. 4 is a cross-sectional view illustrating another example of an anti-reflection structure based on some implementations of the disclosed technology.

As shown in FIG. 4, in addition to the serrated pattern formed over the metal line 334, another serrated pattern may be formed over the other metal line 337 disposed over the metal line 334.

The example illustrated in FIG. 2 includes the serrated pattern formed only at the surface of the metal line 334 located adjacent to the substrate layer 320.

However, some of the light beams that penetrated the semiconductor substrate 321 may propagate through a space between neighboring metal lines 334, and those light beams may be reflected from the metal line 337 arranged a different level, so that the reflected light may reach the semiconductor substrate 321.

In some embodiments of the disclosed technology, the serrated pattern may also be formed in a specific region (e.g., a region overlapping with a space between the contiguous metal lines 334) where light escaping from the serrated pattern of the metal lines 334 can reach (e.g., the metal line 337 as discussed above).

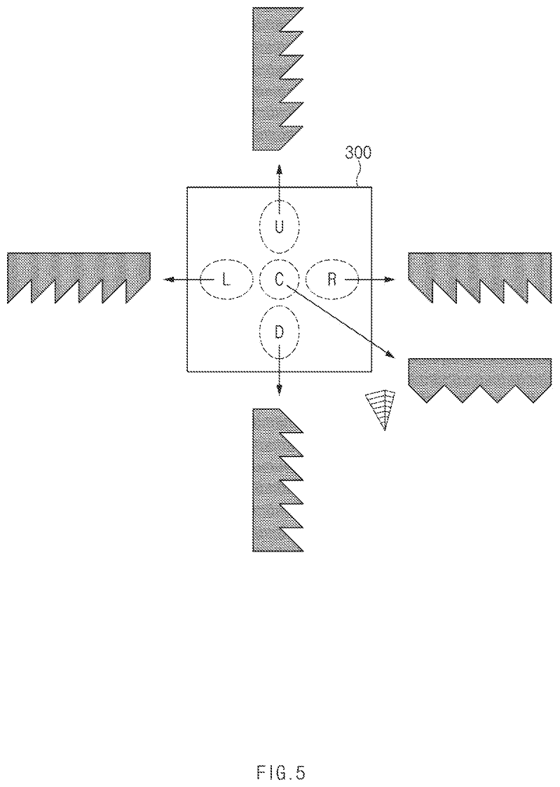

FIG. 5 is a cross-sectional view illustrating another example of the anti-reflection structure based on some implementations of the disclosed technology.

As shown in FIG. 5, the serrated patterns formed in different locations within the pixel array 300 may have different shapes.

For example, serrated patterns each having inverted pyramid shapes may be formed at the center part (C) of the pixel array 300. In other words, the surface of the metal line 334 formed at the center part (C) of the pixel array 300 may be diagonally etched in 4 directions, such that the metal line 334 can be formed to have inverted pyramid-shaped serrated patterns.

In other words, each of the metal lines 334 located in an upper region (U) of the pixel array 300, and each of the other metal lines 334 located in a lower region (D) of the pixel array 300 may have the serrated patterns etched only in one direction (i.e., the serrated patterns etched in the diagonal direction) as shown in FIG. 2. The serrated patterns formed in the upper region (U) and the serrated patterns formed in the lower region (D) may be symmetrical to each other in the diagonal direction.

In addition, each of the metal lines 334 located in the left region (L) of the pixel array 300, and each of the other metal lines 334 located in the right region (R) of the pixel array 300 may have the serrated patterns etched only in one direction (i.e., the serrated patterns etched in the diagonal direction) as shown in FIG. 2. The serrated patterns formed in the left region (L) and the serrated patterns formed in the right region (R) may be symmetrical to each other in the diagonal direction.

That is, the diagonal direction of the serrated pattern of the unit pixels can vary depending on the incident light beam direction.

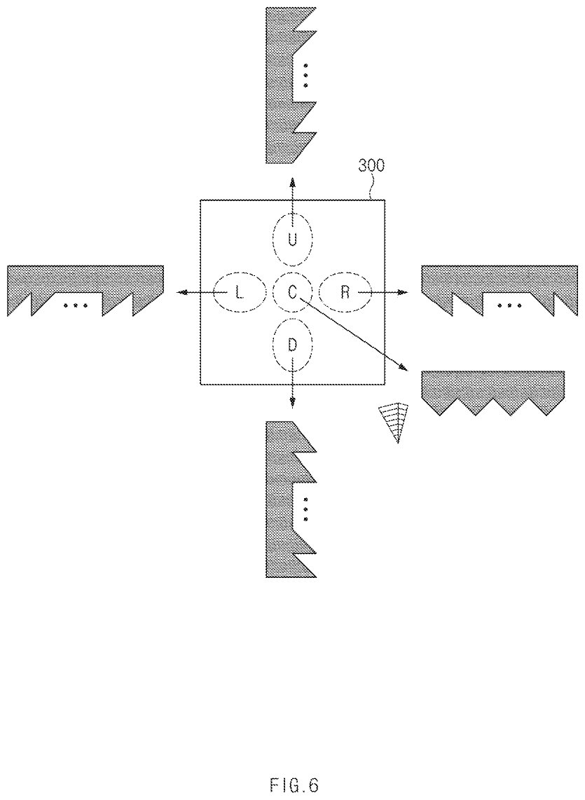

FIG. 6 is a cross-sectional view illustrating another example of an anti-reflection structure based on some implementations of the disclosed technology.

The embodiment of FIG. 5 has disclosed that the diagonal lines of the serrated patterns respectively formed in the regions C, U, D, R, and L of the pixel array 300 have the same slope.

As shown in FIG. 6, the diagonal lines of the serrated patterns may have different slopes according to the positions thereof within the pixel array 300.

For example, the metal lines 334 located at the center part (C) of the pixel array 300 may have the inverted pyramid-shaped serrated pattern as shown in FIG. 4.

The metal lines 334 located in the upper region (U), the lower region (D), the left region (L), and the right region (R) of the pixel array 300 may have the serrated patterns etched only in one direction (i.e., in the diagonal direction). In this case, the slope of the diagonal line may gradually increase as being closer to the edge region of the pixel array 300.

As is apparent from the above description, the image sensing device based on the embodiments of the disclosed technology can avoid a distance calculation error by preventing light beams that propagate the semiconductor substrate from being reflected from the metal line, and by preventing the light beams from being directed to the semiconductor substrate.

Although a number of illustrative embodiments have been described, it should be understood that numerous other modifications and embodiments can be devised based on this disclosure. Particularly, numerous variations and modifications are possible in the component parts and/or arrangements within the scope of the disclosure of this patent document. In addition to variations and modifications in the component parts and/or arrangements, alternative uses may be apparent to those ordinarily skilled in the art.

What is claimed is:

1. An image sensing device comprising:
a semiconductor substrate including a first surface and a second surface on two opposite sides of the semiconductor substrate, and configured to include a plurality of unit pixels, each of which is configured to generate a pixel signal based on light incident upon the first surface; and
metal lines disposed over the second surface of the semiconductor substrate, and configured to carry the pixel signal generated from the semiconductor substrate and electrical signals used to generate the pixel signal,
wherein at least one of the metal lines includes an anti-reflection structure having a shape to direct light that propagates in the semiconductor substrate and is reflected from the metal lines to directions other than a direction toward the semiconductor substrate.

2. The image sensing device according to claim 1, wherein the metal lines include:
first metal lines coupled to either the semiconductor substrate or a pixel transistor formed in the semiconductor substrate through a first contact plug, and configured to have the anti-reflection structure; and
second metal lines formed over the first metal lines, and coupled to the first metal lines through a second contact plug.

3. The image sensing device according to claim 2, further comprising:
a light delay film disposed between the semiconductor substrate and the first metal lines, and configured to reduce a propagation speed of light.

4. The image sensing device according to claim 3, wherein the light delay film includes at least one of a high-permittivity material film and a high-permeability material film.

5. The image sensing device according to claim 4, wherein:
the high-permittivity material film includes at least one of aluminum oxide (Al₂O₃), hafnium oxide (HfO₂), zirconium oxide (ZrO₂), hafnium silicate (HfSiO, HfSiO₄), zirconium silicon oxide (ZrSiO), yttrium oxide (Y₂O₃), tantalum oxide (Ta₂O₅), or titanium oxide (TiO₂); and
the high-permittivity material film includes a ferromagnetic material.

6. The image sensing device according to claim 1, wherein the anti-reflection structure includes:
serrated patterns structured to direct the light reflected at a surface of the serrated patterns to directions other than a direction toward the semiconductor substrate.

7. The image sensing device according to claim 6, further comprising:
an anti-reflection film formed along a diagonal region of the serrated patterns.

8. The image sensing device according to claim 2, wherein the semiconductor substrate includes:
a control region configured to generate carrier currents based on a voltage at one of the first metal lines; and
a detection region coupled to one of the first metal lines, and configured to capture electrons flowing in the semiconductor substrate by the carrier currents.

9. The image sensing device according to claim 8, wherein:
the control region includes a P-type impurity region; and
the detection region includes an N-type impurity region.

10. The image sensing device according to claim 2, wherein the anti-reflection structure is further formed in a region of the second metal lines where light escaping from the serrated pattern of the first metal lines reaches.

11. The image sensing device according to claim 1, wherein, in a pixel array in which the plurality of unit pixels is arranged in a first direction and a second direction perpendicular to the first direction, the anti-reflection structure includes:
a first serrated pattern formed in metal lines located at a center part of the pixel array, and diagonally etched in first, second, third, and fourth directions;
a second serrated pattern formed in metal lines located in a first region of the center part, and diagonally etched only in the first direction;
a third serrated pattern formed in metal lines located in a second region of the center part, and diagonally etched only in the second direction symmetrical to the first direction;
a fourth serrated pattern formed in metal lines located in a third region of the center part, and diagonally etched only in the third direction; and
a fifth serrated pattern formed in metal lines located in a fourth of the center part, and diagonally etched only in the fourth direction symmetrical to the third direction.

12. The image sensing device according to claim 11, wherein slopes of diagonal lines of the second to fifth serrated patterns are gradually increased as being closer to an edge region of the pixel array.

13. An image sensing device comprising:
a substrate layer including a plurality of unit pixels, each of which is configured to generate a pixel signal based on light incident upon a first surface; and
metal lines disposed over a second surface of the substrate layer located to face away from the first surface, and coupled to the substrate layer,
wherein the metal lines include serrated patterns formed at a surface facing the substrate layer.

14. The image sensing device according to claim 13, wherein the substrate layer includes a semiconductor substrate,
wherein the semiconductor substrate includes:
a control region configured to generate carrier currents based on a voltage at the metal lines; and
a detection region configured to capture electrons flowing in the semiconductor substrate by the carrier currents.

15. The image sensing device according to claim 13, wherein the serrated patterns include:
at least one diagonal region formed by etching at least one side of at least one of the metal lines such that the at least one side of at least one of the metal lines includes inclined portions consecutively arranged along the at least one side of at least one of the metal lines.

16. The image sensing device according to claim 15, wherein the metal lines further include:
an anti-reflection film formed along the serrated diagonal region.

17. The image sensing device according to claim 13, wherein, in a pixel array in which the plurality of unit pixels is arranged in a first direction and a second direction perpendicular to the first direction, the serrated pattern includes:
a first serrated pattern formed in metal lines located at a center part of the pixel array, and diagonally etched in first, second, third, and fourth directions;
a second serrated pattern formed in metal lines located in a first region of the center part, and diagonally etched only in the first direction;
a third serrated pattern formed in metal lines located in a second region of the center part, and diagonally etched only in the second direction symmetrical to the first direction;
a fourth serrated pattern formed in metal lines located in a third region of the center part, and diagonally etched only in the third direction; and
a fifth serrated pattern formed in metal lines located in a fourth region of the center part, and diagonally etched only in the fourth direction symmetrical to the third direction.

18. The image sensing device according to claim 17, wherein slopes of diagonal lines of the second to fifth serrated patterns are gradually increased as being closer to an edge region of the pixel array.

19. The image sensing device according to claim 13, further comprising:
a light delay film disposed between the semiconductor substrate and the metal lines, and configured to reduce a propagation speed of light.

20. The image sensing device according to claim 19, wherein the light delay film includes at least one of a high-permittivity material film and a high-permeability material film.
